(19) United States
(12) Patent Application Publication
(10) Pub. No.: US 2001/0046127 A1
(43) Pub. Date: Nov. 29, 2001

(54) SEMICONDUCTOR PACKAGE AND DEVICE SOCKET

(76) Inventor: SHIGERU MATSUMURA, TOKYO (JP)

Correspondence Address: OBLON SPIVAK MCCLELLAND MAIER & NEUSTADT, 1755 JEFFERSON DAVIS HIGHWAY, FOURTH FLOOR, ARLINGTON, VA, 22202

(21) Appl. No.: 09/147,311

(22) PCT Filed: May 28, 1997
(86) PCT No.: PCT/JP97/01809

§ 371 Date: None

(30) Foreign Application Priority Data
May 30, 1996 (JP) 136508/1996

(51) Int. Cl. H05K 7/02; H05K 7/06

(52) U.S. Cl. 361/783; 361/807; 174/260

(57) ABSTRACT

A semiconductor package (11) has a board (12) which mounts a semiconductor chip on one surface and arranges a plurality of external terminals (14) on the other surface at a predetermined pitch. Then, positioning holes (13) are formed at more than one desired positions on said board (12) so as to secure the accuracy of the dimensions between the hole and any one of the external terminals (14a).

### TECHNICAL FIELD

The present invention relates to a structure of a semiconductor package and a device socket which is capable of detachably mounting the semiconductor package thereon.

### BACKGROUND ART

When operations of semiconductor devices are checked after completion of manufacturing semiconductor packages or on shipping them, checking is generally performed under a state where the semiconductor package is fitted to a socket. A conventional device socket for a BGA (Ball Grid Array) which is an example of a semiconductor package has the following structure.

FIGS. 1(a), 1(b) and 1(c) show a BGA package which is an example of a conventional semiconductor package. FIG. 1(a) is a plan view, FIG. 1(b) is a side view and FIG. 1(c) is a bottom view. FIG. 2 is a perspective view showing a conventional structure of the device socket for the BGA package.

The BGA package shown in FIGS. 1(a), 1(b) and 1(c) uses a circuit board 2 having a dimension a×b, on the rear surface of which external terminals 3, for example, ball shaped soldering bumps, are disposed in a matrix fashion and on the front surface of which a semiconductor chip sealed with an insulating resin 2 is mounted. In FIGS. 1(a), 1(b) and 1(c), for the sake of convenience, the small number of external terminals 3 are illustrated. In case of the BGA package, the external terminals 3 are normally arranged. However, actually, the large number of the external terminals 3 are arranged with a small pitch. Moreover, an electrode (not shown) of the semiconductor chip and the external terminal 3 are connected through a wiring pattern (not shown) of the circuit board 1.

A device socket 5 of FIG. 2 used when operations of such BGA packages are checked has a mounting surface 8 where the BGA package 4 is mounted. On the mounting surface 8, a plurality of contact elements 7 are arranged, each corresponding to the corresponding one of the external terminals 3 of the BGA package 4, whereby a wiring (not shown) outside the socket and the external terminals 3 can be electrically connected. Furthermore, on the mounting surface 8 of the device socket 5, a guide portions 6 are formed in conformity with the external shape of the board of the BGA package 4. Thus, positioning of the external terminals 3 of the BGA package with respect to the contact elements 7 is performed based on the external shape of the board.

However, in general, the external dimension a×b of the board of the BGA package as described above does not have good accuracy. Furthermore, the dimensions a′ and b′ from the end of the circuit board 1 to the external terminal 3 shown in FIG. 1(c) is not especially defined. If the dimensions a′ and b′ were defined, their accuracy would be low.

Therefore, the device socket, in which the positioning of the external terminal with respect to the contact element is performed based on the external shape of the board using the guide portions 6 as described above, has the problem that it is difficult to secure the positioning accurately.

Furthermore, even in devices having the same standards, the dimensions of the external shape of the boards are somewhat different from each other depending on manufacturers. Therefore, dimensions of the guide portions of the device socket are different, so that the problem of lack of wide use arises.

### DISCLOSURE OF INVENTION

From the viewpoint of the problem of the prior art, an object of the present invention is to provide a semiconductor package which has a structure such that positioning of an external terminal thereof with a contact element of a socket can be performed with a high accuracy and which is capable of wider usability. Another object of the present invention is to provide a device socket used for this semiconductor package.

To achieve the foregoing objects, the semiconductor package of the present invention is characterized in that a board is provided which mounts a semiconductor chip on one surface thereof and arranges a plurality of external terminals on the other surface thereof at a predetermined pitch and a positioning hole is formed in at least more than one position in the foregoing board so as to secure the accuracy in dimensions between the positioning hole and any one of the external terminals.

The foregoing positioning hole is a notch hole or a round hole. The semiconductor device constituted as above can be applied to packages in forms such as SGA, LGA, SON and KGD.

Furthermore, the present invention includes also a device socket which is capable of fitting the foregoing semiconductor package, the device socket comprising a plurality of contact elements, each being capable of contacting with the corresponding one of the external terminals of the foregoing semiconductor package and a positioning pin which is engaged with the positioning hole and guides the foregoing external terminals along the foregoing contact elements.

In the invention described above, the accuracy in the dimensions between any one of the external terminals and the positioning hole is secured in the semiconductor package. Therefore, when the positioning pin of the socket is inserted into the positioning hole of the semiconductor package, the accuracy of the dimensions between the positioning pin and the external terminals can be also secured. Thus, positionings of the contact elements of the socket with respect to the external terminals of the semiconductor package can be performed with a high accuracy without being affected by the accuracy of the dimensions or the external shape of the semiconductor package like the conventional structure, thereby increasing reliability in measurement.

Furthermore, guiding for positioning can be conducted without depending on the external shape of the semiconductor device. Thus, if the position of the positioning hole is defined among the semiconductor packages of the same standard, the same device socket will be used even when manufacturers are different, thereby enhancing its usability.

### BRIEF DESCRIPTION OF DRAWINGS

FIGS. 1(a)˜1(c) show an example of a BGA package which is an example of a conventional semiconductor package, specifically,

FIG. 1(a) is a plan view,

FIG. 1(b) is a side view, and

FIG. 1(c) is a bottom view.

FIG. 2 is a perspective view illustrating a conventional structure of a testing socket for a semiconductor package.

FIGS. 3(a) and 3(b) show an embodiment of a semiconductor package of the present invention, specifically,

FIG. 3(a) is a plan view, and

FIG. 3(b) is a bottom view.

FIG. 4 is a perspective view showing a device socket for the semiconductor package shown in FIGS. 3 (a) and 3 (b).

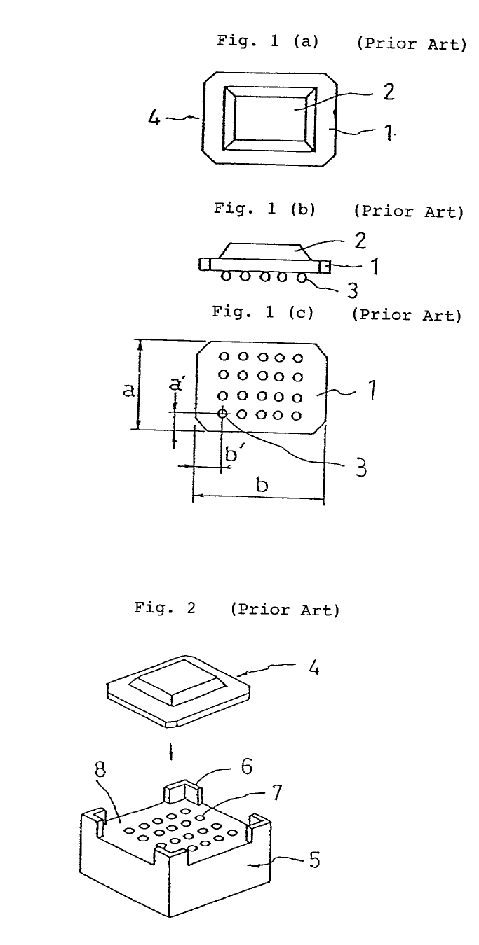

### BEST MODE FOR CARRYING OUT THE INVENTION

An embodiment of the present invention will be described with reference to the accompanying drawings below.

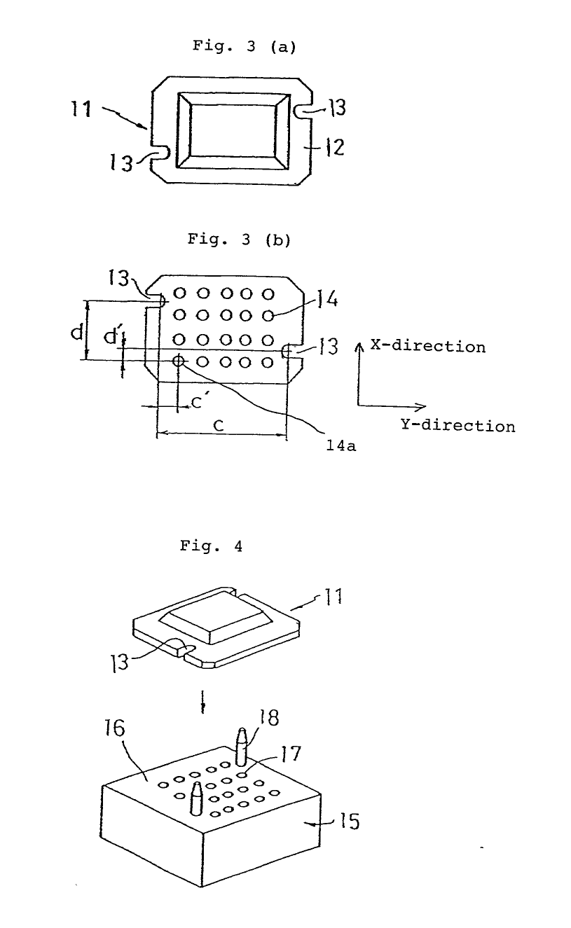

FIGS. 3(a) and 3(b) show an embodiment of a semiconductor package of the present invention. FIG. 3(a) is a plan view and FIG. 3(b) is a bottom view. FIG. 4 is a perspective view showing a device socket used for the semiconductor package shown in FIGS. 3(a) and 3(b).

The semiconductor package 11 of the embodiment of the present invention shown in FIG. 3 is formed by, for example, a BGA package which uses a circuit board 12 having a plurality of external terminals 14 arranged in a matrix fashion on its rear surface, the circuit board having a semiconductor chip mounted on its surface. The semiconductor package 11 seals the semiconductor chip with insulating resin. These external terminals 14 are arranged with a predetermined fine pitch based on a standard, using ball-shaped soldering bumps or cylindrical land portions. Electrodes (not shown) of the semiconductor chip and the external terminals 14 are connected through a wiring pattern (not shown) of the board 12.

Moreover, notches 13 serving as positioning hole is formed in at least more than one desired point of the board 12, while securing the accuracy of the dimensions between the notch 13 and any one of the external terminals. For example, as shown in FIG. 3(b), one notch 13 is formed by cutting the board 12 from one end of the board 12 (the end on the left side of FIG. 3(b)) to the position on the coordinates so that the distance from the center of the notch 13 to that of the predetermined external terminal 14a along the long edge direction of the semiconductor package 11 (the Y-direction in FIG. 3(b)) is c′ and the distance from the center of the notch 13 to that of the external terminal 14a along the short edge direction of the semiconductor package 11 (the X-direction of FIG. 3(b)) is d. Furthermore, the other notch 13 is formed by cutting the board 12 from the other end of the board 12 (the end on the right side of FIG. 3(b)) to the position on the coordinates so that the distance from the center of the other notch 13 to that of the predetermined external terminal 14a along the short edge direction of the semiconductor package 11 (the X-direction in FIG. 3(b)) is d′ and the distance from the center of the other notch 13 to that of the external terminal 14a along the long edge direction of the semiconductor package 11 (the Y-direction of FIG. 3(b)) is c-c′ (c minus c′).

It should be noted that through holes may be formed in points on the coordinates using the predetermined external terminal 14a as a standard, instead of the positioning notch 13.

On the other hand, the device socket 15 of FIG. 4 used when the foregoing semiconductor package 11 is checked has a mounting surface 16 where the semiconductor package 11 is mounted like the conventional example. A plurality of contact elements 17, each corresponding to the corresponding one of the external terminals 14 of the semiconductor package 11, are arranged on this mounting surface 16, whereby the external terminals 14 and a wiring (not shown) outside the socket can be electrically connected. Furthermore, a positioning guide pin 18 standing from the mounting surface 16 is formed so as to correspond to the position of the positioning notch 13 when the external terminal 14 contacts with the contact element 17 with a high accuracy. Specifically, the guide pin 18 is formed in the same dimensions as those of the notch 13 on the mounting surface 16 basing the position of the contact element on the external terminal which serves as a standard for forming the notch 13 of the foregoing semiconductor package 11.

With such structure, when the semiconductor package 11 is fitted to the socket 15 by inserting the positioning guide pin 18 to the positioning notch 13, the external terminal 14 of the semiconductor package 11 fits with the contact element 17 of the socket 15 with a high accuracy, whereby reliability in checking is enhanced.

Since the semiconductor package of this embodiment of the present invention has a structure such that guiding for positioning can be conducted without depending on the external shape of the semiconductor package, the same device socket can be used by defining the position of the positioning hole in the semiconductor package of the same standard, even the manufacturers thereof are different, resulting in widening usability.

Furthermore, the foregoing semiconductor package can be applicable to various kinds of packages such as an LGA (Land Grid Array), an SON (Small Outline Nonleaded package) and KGD (Known Good Die) besides the BGA (Ball Grid Array), as long as such applications do not depart from the scope of the present invention.

As described above, according to the present invention, by providing a semiconductor package having a board where the positioning pin is formed while securing the accuracy of the dimensions between any one of the external terminals and a device socket in which at least one positioning pin corresponding to the foregoing positioning hole is formed, the external terminal of the semiconductor package can be fitted with the contact element of the socket with a high accuracy without being affected by the accuracy of the external shape dimension of the semiconductor package as in the conventional structure, thereby increasing reliability in checking.

Furthermore, since guiding for positioning can be conducted without depending on the external shape of the semiconductor package, the same device socket can be used even when the manufacturers thereof are different, by defining the position of the positioning hole in the semiconductor package of the same standard.

1. A semiconductor package comprising:
a board (12) which mounts a semiconductor chip on one surface thereof and arranges many external terminals (14) at a predetermined pitch on the other surface,
wherein positioning holes (13) are formed in at least two positions on said board (12) while securing the accuracy of the dimensions between said hole and any one of said external terminals (14a).

2. The semiconductor package according to claim 1, wherein said positioning hole (13) is either a notch or a hole.

3. The semiconductor package according to claim 2, wherein said semiconductor package is a BGA package, an LGA package, an SON package or a KGD package.

4. In a device socket (15) which is capable of fitting the semiconductor package (11) according to any one of claims 1, 2 and 3, the improvement comprising:
a plurality of contact elements (17), each being capable of contacting with the corresponding one of the external terminals (14) of said semiconductor package (11): and
positioning pins (18), each being engaged with the corresponding one of said positioning holes (13) to guide said external terminal (14) to said contact element (17).
